(19) United States
(12) Patent Application Publication
(10) Pub. No.: US 2024/0395660 A1
(43) Pub. Date: Nov. 28, 2024

(54) THERMAL MANAGEMENT MODULE OF AN INTEGRATED CIRCUIT ASSEMBLY

(71) Applicant: Apple Inc., Cupertino, CA (US)

(72) Inventors: Halil Berberoglu, Saratoga, CA (US); Cheng P. Tan, Fremont, CA (US); Jifang Tian, Fremont, CA (US); Chetan Harsha Edara, Santa Clara, CA (US); Pavan Kumar Varma Buddaraju, Milpitas, CA (US); Scott J. Campbell, Mountain View, CA (US)

(21) Appl. No.: 18/200,365

(22) Filed: May 22, 2023

(51) Int. Cl. H01L 23/427

(52) U.S. Cl. CPC H01L 23/427

(57) ABSTRACT

A thermal management module for an integrated circuit assembly includes a housing defining a configured to receive a fluid and having a variable cross-sectional area. The thermal management module also includes a wick disposed within the sealed passage, where the wick forms pores configured to convey a liquid form of the fluid toward an evaporator section of the thermal management module. The thermal management module also includes a void formed within the sealed passage between the wick and a wall of the housing, wherein the void is configured to convey a vapor form of the fluid toward a condenser section of the thermal management module.

### BACKGROUND

The present disclosure generally relates to thermal management of a semiconductor die, semiconductor package, integrated circuit assembly, printed circuit board, system-level printed circuit board, or electronic device (e.g., a smartphone or other computing device), and more particularly, to a thermal management module having various features enabling a relatively thin form factor and relatively high heat transfer efficiency of the thermal management module.

In mobile devices, thermal management is an important design factor. In particular, components associated with data processing (e.g., a system-on-chip or SoC) may produce relatively high levels of thermal output. While traditional configurations, such as heat pipes, provide some level of heat transfer from data processing components to, for example, an enclosure of the mobile device and/or an ambient environment, such traditional configurations may be relatively large (e.g., thick), expensive, and/or inefficient.

### SUMMARY

In one embodiment, a thermal management module for an integrated circuit assembly includes a housing defining a sealed passage configured to receive a fluid and having a variable cross-sectional area. The thermal management module also includes a wick disposed within the sealed passage, where the wick forms pores configured to convey a liquid form of the fluid toward an evaporator section of the thermal management module. The thermal management module also includes a void formed within the sealed passage between the wick and a wall of the housing, where the void is configured to convey a vapor form of the fluid toward a condenser section of the thermal management module.

In another embodiment, a thermal management module for an integrated circuit assembly a sealed passage configured to house a fluid, and an evaporator section in the sealed passage, where the evaporator section is configured to extract heat from the integrated circuit assembly via the fluid to generate a vapor form of the fluid. The thermal management module also includes a condenser section in the sealed passage, where the condenser section is configured to extract heat from the fluid to generate a liquid form of the fluid. The thermal management module also includes a wick disposed within the sealed passage and forming pores configured to convey the liquid form of the fluid from the condenser section toward the evaporator section. The thermal management module also includes a void formed within the sealed passage adjacent to the wick, where the void is configured to convey the vapor form of the fluid from the evaporator section toward the condenser section.

In another embodiment, an integrated circuit assembly includes a substrate having processing circuitry thereon. The integrated circuit assembly also includes an evaporator section spatially aligned with the processing circuitry and configured to extract heat from the processing circuitry via a fluid to generate a vapor form of the fluid, and a condenser section positioned away from the processing circuitry and configured to extract heat from the fluid to generate a liquid form of the fluid. The thermal management module also includes a wick spanning the evaporator section and the condenser section, where the wick forms pores configured to convey the liquid form of the fluid from the condenser section toward the evaporator section. The thermal management module also includes a void formed adjacent to the wick and spanning the evaporator section and the condenser section, where the void is configured to convey the vapor form of the fluid from the evaporator section toward the condenser section.

In another embodiment, a method of manufacturing a thermal management module for an integrated circuit assembly includes disposing a powder on a surface of a housing of the thermal management module, the surface spanning a condenser section of the thermal management module and an evaporator section of the thermal management module. The method also includes heating the powder to form a sintered powder layer on the surface. The method also includes disposing a fluid in the housing, and sealing the housing to form a sealed passage in which the sintered powder layer, a void between the sintered powder layer and the housing, and the fluid are disposed.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts:

FIG. 1 is a block diagram of an electronic device, in accordance with an embodiment of the present disclosure;

FIG. 2 is a perspective view of the electronic device of FIG. 1 in the form of a notebook computer, in accordance with an embodiment of the present disclosure;

FIG. 3 is a front view of the electronic device of FIG. 1 in the form of a handheld device, in accordance with an embodiment of the present disclosure;

FIG. 4 is a front view of the electronic device of FIG. 1 in the form of portable tablet computer, in accordance with an embodiment of the present disclosure;

FIG. 5 is a front view of the electronic device of FIG. 1 in the form of a desktop computer, in accordance with an embodiment of the present disclosure;

FIG. 6 is a front and side view of the electronic device of FIG. 1 in the form of a wearable electronic device, in accordance with an embodiment of the present disclosure;

FIG. 7 is a front view of a portion of a thermal management module for the electronic device of FIG. 1, including a sintered powder layer and one or more columns (e.g., pillars) aligned with processing circuitry of an integrated circuit assembly, in accordance with an embodiment of the present disclosure;

FIG. 8 is a front view of a portion of a thermal management module for the electronic device of FIG. 1, including a sintered powder layer aligned with processing circuitry of an integrated circuit assembly, in accordance with an embodiment of the present disclosure;

FIG. 9 is a front view of a portion of a thermal management module for the electronic device of FIG. 1, including a sintered powder layer aligned with processing circuitry of an integrated circuit assembly, and a passive spreader aligned with dynamic random-access memory (DRAM) circuitry, in accordance with an embodiment of the present disclosure;

FIG. 10 is a front view of a portion of a thermal management module for the electronic device of FIG. 1, including a sintered powder layer aligned with processing circuitry of an integrated circuit assembly and aligned with dynamic random-access memory (DRAM), in accordance with an embodiment of the present disclosure;

FIG. 11 is a cross-sectional side view of a portion of a thermal management module for the electronic device of FIG. 1, including an evaporator section recessed downwardly from an integrated circuit assembly platform corresponding to an integrated circuit assembly, in accordance with an embodiment of the present disclosure;

FIG. 12 is a cross-sectional side view of a portion of a thermal management module for the electronic device of FIG. 1, including an evaporator section elevated upwardly to an integrated circuit assembly platform corresponding to the integrated circuit assembly, in accordance with an embodiment of the present disclosure;

FIG. 13 is a cross-sectional side view of a portion of a thermal management module for the electronic device of FIG. 1, including an evaporator section recessed downwardly from an integrated circuit assembly platform corresponding to the integrated circuit assembly, where a first housing portion of the thermal management module includes a first material (e.g., copper) at the integrated circuit assembly platform and a second material (e.g., stainless steel), in accordance with an embodiment of the present disclosure;

FIG. 14 is a cross-sectional side view of a portion of a thermal management module for the electronic device of FIG. 1, including an evaporator section recessed downwardly from an integrated circuit assembly platform corresponding to the integrated circuit assembly, where a first housing portion includes clad material (e.g., stainless steel-copper clad material), in accordance with an embodiment of the present disclosure;

FIG. 15 is a cross-sectional side view of a portion of a thermal management module for the electronic device of FIG. 1, including an evaporator section recessed downwardly from an integrated circuit assembly platform corresponding to the integrated circuit assembly, where both a first housing portion and a second housing portion include a clad material (e.g., stainless steel-copper clad material), in accordance with an embodiment of the present disclosure;

FIG. 16 is a cross-sectional side view of a portion of a thermal management module for the electronic device of FIG. 1, including an adiabatic section or condenser section having a first height that is less than a second height of each of the evaporator sections illustrated in FIGS. 11-15, in accordance with an embodiment of the present disclosure;

FIG. 17 is an exploded perspective view of a thermal management module for the electronic device of FIG. 1, in accordance with an aspect of the present disclosure;

FIG. 18 is a top view of a thermal management module for the electronic device of FIG. 1, including a sintered powder layer with substantially constant width through adiabatic sections and condenser sections of the thermal management module, in accordance with an embodiment of the present disclosure;

FIG. 19 is a top view of a thermal management module for the electronic device of FIG. 1, including a sintered powder layer with greater width in condenser sections of the thermal management module than in adiabatic sections of the thermal management module, where a cross-section of the sintered powder layer at the condenser sections is tapered, in accordance with an embodiment of the present disclosure;

FIG. 20 is a top view of a thermal management module for the electronic device of FIG. 1, including a sintered powder layer with greater width in condenser sections of the thermal management module than in adiabatic sections of the thermal management module, where a cross-section of the sintered powder layer at the condenser sections is not tapered, in accordance with an embodiment of the present disclosure;

FIG. 21 is a front cross-sectional view of a portion of an evaporator section of a thermal management module for the electronic device of FIG. 1, including columns with a curvilinear, non-circular (e.g., oval or elliptical) cross-sections and configured to extend from a sintered powder layer of the thermal management module to an integrated circuit assembly platform of the thermal management module, in accordance with an embodiment of the present disclosure;

FIG. 22 is a front cross-sectional view of a portion of an evaporator section of a thermal management module for the electronic device of FIG. 1, including columns with a rectangular or strip-shaped cross-section and configured to extend from a sintered powder layer of the thermal management module to an integrated circuit assembly platform of the thermal management module, in accordance with an embodiment of the present disclosure;

FIG. 23 is a front cross-sectional view of a portion of an evaporator section of a thermal management module for the electronic device of FIG. 1, including columns with cross-sections forming a herringbone-like pattern and configured to extend from a sintered powder layer of the thermal management module to an integrated circuit assembly platform of the thermal management module, in accordance with an embodiment of the present disclosure;

FIG. 24 is a front cross-sectional view of a portion of an evaporator section of a thermal management module for the electronic device of FIG. 1, including columns with circular cross-sections and configured to extend from a sintered powder layer of the thermal management module to an integrated circuit assembly platform of the thermal management module, in accordance with an embodiment of the present disclosure;

FIG. 25 is a front cross-sectional view of a portion of an evaporator section of a thermal management module for the electronic device of FIG. 1, including columns with trapezoidal cross-sections and configured to extend from a sintered powder layer of the thermal management module to an integrated circuit assembly platform of the thermal management module, in accordance with an embodiment of the present disclosure;

FIG. 26 is a cross-sectional side view of a sealing mechanism for sealing first and second housing portions of a housing of a thermal management module for the electronic device of FIG. 1, the sealing mechanism including a brazing material disposed in a seam between the first and second housing portions, in accordance with an embodiment of the present disclosure;

FIG. 27 is a cross-sectional side view of a sealing mechanism for sealing first and second housing portions of a housing of a thermal management module for the electronic device of FIG. 1, the sealing mechanism including a lap weld between the first and second housing portions and oriented in a first direction, in accordance with an embodiment of the present disclosure;

FIG. 28 is a cross-sectional side view of a sealing mechanism for sealing first and second housing portions of a housing of a thermal management module for the electronic device of FIG. 1, the sealing mechanism including at least one lap weld between the first and second housing portions, in accordance with an embodiment of the present disclosure;

FIG. 29 is a cross-sectional side view of a sealing mechanism for sealing first and second housing portions of a housing of a thermal management module for the electronic device of FIG. 1, the sealing mechanism including a lap weld between the first and second housing portions and oriented in a second direction different than the first direction of FIG. 27, in accordance with an embodiment of the present disclosure; and

FIG. 30 is a process flow diagram illustrating a method of manufacturing a thermal management module for the electronic device of FIG. 1, in accordance with an embodiment of the present disclosure.

### DETAILED DESCRIPTION OF SPECIFIC EMBODIMENTS

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on.

The present disclosure is directed to a thermal management module for an integrated circuit assembly, such as a system-on-chip (SoC). As described in detail below, the thermal management module includes various features that enable a relatively thin form factor and a relatively high heat transfer efficiency compared to traditional configurations.

For example, the thermal management module, referred to in certain instances of the present disclosure as a vapor chamber, includes a housing configured to define a passage configured to receive a fluid. In some embodiments, the housing includes a first housing portion and a second housing portion coupled to the first housing portion to seal the passage (e.g., fluid passage) of the thermal management module. For example, a brazing material may be disposed in a seam formed by the first housing portion and the second housing portion such that the brazing material, the first housing portion, and the second housing portion hermetically seal the passage of the thermal management module. Additionally or alternatively, a lap weld along a first perimeter of the first housing portion and a second perimeter of the second housing portion may hermetically seal the passage of the thermal management module. The above-described configuration can be distinguished from a traditional configuration employing, for example, a cylindrically-shaped heat pipe that is compressed to reduce a thickness of the heat pipe. Such traditional configurations may suffer, for example, from cracking, a lack of geometric versatility, relatively low heat transfer efficiency, relatively high cost to manufacture and/or operate, etc.

In accordance with the present disclosure, a wick (e.g., a sintered powder layer) forming pores is disposed in the passage defined by the housing of the thermal management module. While certain instances of the present disclosure refer to a “sintered powder layer” below, it should be understood other types of wicks are also contemplated by the present disclosure, such as a gel (e.g., a porous gel), a paste (e.g., a porous paste), or a wire (e.g., a porous wire).

The sintered powder layer may be disposed on a surface of the first housing portion facing the passage (e.g., prior to a coupling of the first housing portion with the second housing portion). In general, the sintered powder layer may be formed by heating a powder, such as a copper powder, just below a melting point of the powder, causing a coalescence of the powder particles with pores between various formations of the coalesced powder particles. In general, the pores are configured to convey a liquid form of the fluid received by the passage of the thermal management module. For example, the pores are configured convey the liquid form of the fluid toward an evaporator section of the thermal management module, where the evaporator section is spatially aligned with (e.g., disposed underneath) the integrated circuit assembly. In certain embodiments, a pore size or density may be varied across portions of the sintered powder layer to improve heat transfer efficiency of the thermal management module. For example, a first pore size or density in (or adjacent to) the evaporator section may be less than a second pore size or density in (or adjacent to) a condenser section of the thermal management module.

Further, a void is formed between the sintered powder layer and a wall of the housing of the thermal management module. For example, the void may be disposed between the sintered powder layer and the second housing portion described above. In general, the void is configured to convey a vapor form of the fluid from the evaporator section, through an adiabatic section of the thermal management module, and to the condenser section of the thermal management module. As described above, the evaporator section may be spatially aligned with the integrated circuit assembly cooled by the thermal management module, while the adiabatic section and the condenser section may be spatially offset from the integrated circuit assembly. In this way, heat is transferred from the integrated circuit assembly to the liquid form of the fluid at the evaporator section, causing the liquid form of the fluid to evaporate to the vapor form of the fluid. The vapor form is conveyed (e.g., the void) from the evaporator section, through the adiabatic section, and to the condenser section, where the vapor form of the fluid is cooled and condensed (e.g., by heat fins, an enclosure of the electronic device employing the integrated circuit assembly and corresponding thermal management system, an air mover such as a fan, or any combination thereof). Cooling of the vapor form of the fluid may cause the vapor form to condense back to the liquid form, which is conveyed (e.g., via the pores in the sintered powder layer) from the condenser section, through the adiabatic section, and back to the evaporator section.

In certain embodiments, the integrated circuit assembly is disposed on or otherwise spatially aligned with an integrated circuit assembly platform of the thermal management module, where the integrated circuit assembly platform defines a portion of a boundary of the evaporator section. Further, one or more columns, referred to in certain instances of the present disclosure as one or more pillars, may extend from the sintered powder layer, through the void above the sintered powder layer, and to the integrated circuit assembly platform. The one or more columns may be an additional sintered powder layer (e.g., having fluid-conveying pores), or the one or more columns may be substantially solid (e.g., without fluid-conveying pores). In general, the integrated circuit assembly transfers heat to the integrated circuit assembly platform, which transfers the heat to the one or more columns, which transfers the heat to the sintered powder layer, which transfers the heat to the liquid form of the fluid. Various configurations (e.g., numbers, shapes, geometries, etc.) of the one or more columns are possible in accordance with the present disclosure. These and other features, which are configured to provide a relatively thin, relatively efficient, and relatively cost-effective thermal management module for integrated circuit assemblies, are described in detail below with reference to the drawings.

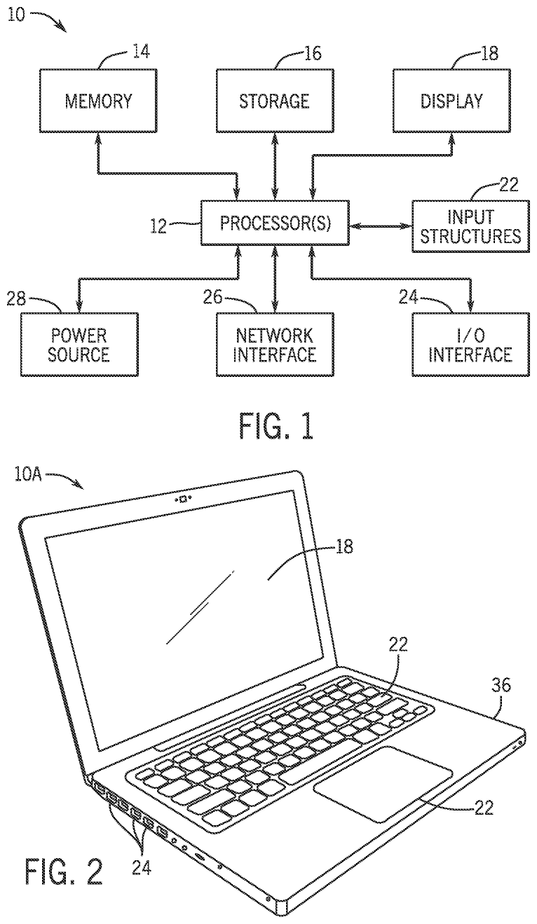

With the foregoing in mind, a general description of suitable electronic devices that may employ switching mixed topology regulators in their circuitry will be provided below. Turning first to FIG. 1, an electronic device 10 according to an embodiment of the present disclosure may include, among other things, one or more processor(s) 12, memory 14, nonvolatile storage 16, a display 18, input structures 22, an input/output (I/O) interface 24, a network interface 26, and a power source 28. The various functional blocks shown in FIG. 1 may include hardware elements (including circuitry), software elements (including computer code stored on a computer-readable medium) or a combination of both hardware and software elements. It should be noted that FIG. 1 is merely one example of a particular implementation and is intended to illustrate the types of components that may be present in electronic device 10.

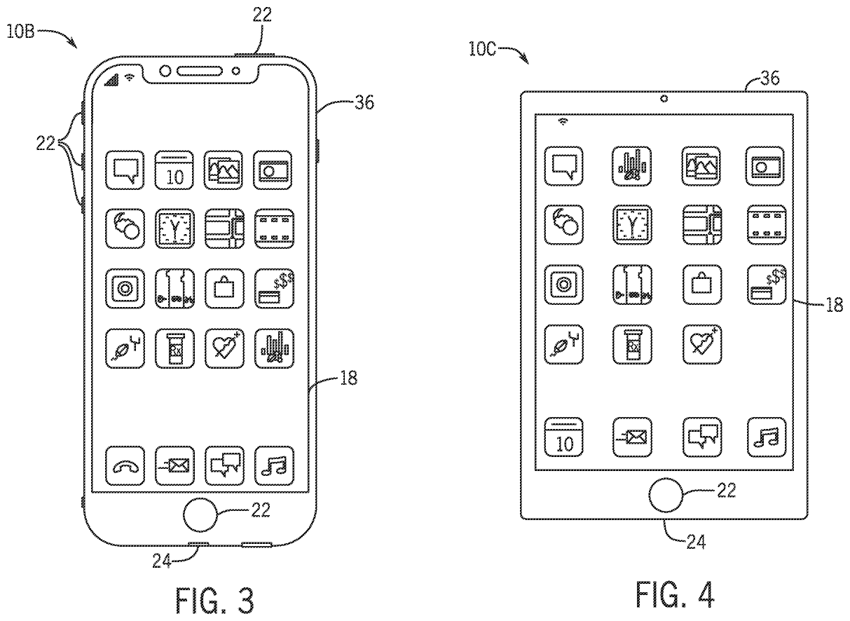

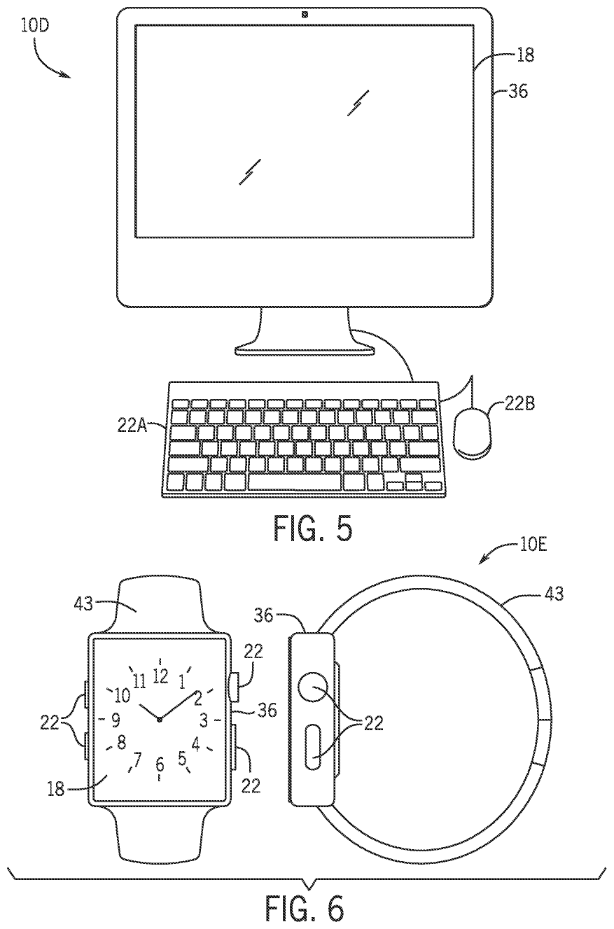

By way of example, the electronic device 10 may represent a block diagram of the notebook computer depicted in FIG. 2, the handheld device depicted in FIG. 3, the handheld device depicted in FIG. 4, the desktop computer depicted in FIG. 5, the wearable electronic device depicted in FIG. 6, or similar devices. It should be noted that the processor(s) 12 and other related items in FIG. 1 may be generally referred to herein as “data processing circuitry.” Such data processing circuitry may be embodied wholly or in part as software, firmware, hardware, or any combination thereof. Furthermore, the data processing circuitry may be a single contained processing module or may be incorporated wholly or partially within any of the other elements within the electronic device 10.

In the electronic device 10 of FIG. 1, the processor(s) 12 may be operably coupled with the memory 14 and the nonvolatile storage 16 to perform various algorithms. Such programs or instructions executed by the processor(s) 12 may be stored in any suitable article of manufacture that includes one or more tangible, computer-readable media at least collectively storing the instructions or routines, such as the memory 14 and the nonvolatile storage 16. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor(s) 12 to enable the electronic device 10 to provide various functionalities.

In certain embodiments, the display 18 may be a liquid crystal display (LCD), which may allow users to view images generated on the electronic device 10. In some embodiments, the display 18 may include a touch screen, which may allow users to interact with a user interface of the electronic device 10. Furthermore, it should be appreciated that, in some embodiments, the display 18 may include one or more organic light emitting diode (OLED) displays, or some combination of LCD panels and OLED panels.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. The network interface 26 may include, for example, one or more interfaces for a personal area network (PAN), such as a Bluetooth network, for a local area network (LAN) or wireless local area network (WLAN), such as an 802.11x Wi-Fi network, and/or for a wide area network (WAN), such as a 3rd generation (3G) cellular network, 4th generation (4G) cellular network, Long-Term Evolution (LTE) cellular network, Long-Term Evolution license assisted access (LTE-LAA) cellular network, 5th generation (5G) cellular network, or New Radio (NR) cellular network. The network interface 26 may also include one or more interfaces for, for example, broadband fixed wireless access networks (WiMAX), mobile broadband Wireless networks (mobile WiMAX), asynchronous digital subscriber lines (e.g., ADSL, VDSL), digital video broadcasting-terrestrial (DVB-T) and its extension DVB Handheld (DVB-H), ultra-wideband (UWB), alternating current (AC) power lines, and so forth. Network interfaces 26 such as the one described above may benefit from the use of tuning circuitry, impedance matching circuitry and/or noise filtering circuits that may include polymer capacitors such as the ones described herein. As further illustrated, the electronic device 10 may include a power source 28. The power source 28 may include any suitable source of power, such as a rechargeable lithium polymer (Li-poly) battery and/or an alternating current (AC) power converter.

In certain embodiments, the electronic device 10 may take the form of a computer, a portable electronic device, a wearable electronic device, or other type of electronic device. Such computers may include computers that are generally portable (such as laptop, notebook, and tablet computers) as well as computers that are generally used in one place (such as conventional desktop computers, workstations, and/or servers). In certain embodiments, the electronic device 10 in the form of a computer may be a model of a MacBook®, MacBook® Pro, MacBook Air®, iMac®, Mac® mini, or Mac Pro® available from Apple Inc. By way of example, the electronic device 10, taking the form of a notebook computer 10A, is illustrated in FIG. 2 in accordance with one embodiment of the present disclosure. The depicted computer 10A may include a housing or enclosure 36, a display 18, input structures 22, and ports of an I/O interface 24. In one embodiment, the input structures 22 (such as a keyboard and/or touchpad) may be used to interact with the computer 10A, such as to start, control, or operate a GUI or applications running on computer 10A. For example, a keyboard and/or touchpad may allow a user to navigate a user interface or application interface displayed on display 18.

FIG. 3 depicts a front view of a handheld device 10B, which represents one embodiment of the electronic device 10. The handheld device 10B may represent, for example, a portable phone, a media player, a personal data organizer, a handheld game platform, or any combination of such devices. By way of example, the handheld device 10B may be a model of an iPod® or iPhone® available from Apple Inc. of Cupertino, California. The handheld device 10B may include an enclosure 36 to protect interior components from physical damage and to shield them from electromagnetic interference. The enclosure 36 may surround the display 18. The I/O interfaces 24 may open through the enclosure 36 and may include, for example, an I/O port for a hard-wired connection for charging and/or content manipulation using a standard connector and protocol, such as the Lightning connector provided by Apple Inc., a universal serial bus (USB), or other similar connector and protocol.

User input structures 22, in combination with the display 18, may allow a user to control the handheld device 10B. For example, the input structures 22 may activate or deactivate the handheld device 10B, navigate user interface to a home screen, a user-configurable application screen, and/or activate a voice-recognition feature of the handheld device 10B. Other input structures 22 may provide volume control, or may toggle between vibrate and ring modes. The input structures 22 may also include a microphone may obtain a user's voice for various voice-related features, and a speaker may enable audio playback and/or certain phone capabilities. The input structures 22 may also include a headphone input may provide a connection to external speakers and/or headphones.

FIG. 4 depicts a front view of another handheld device 10C, which represents another embodiment of the electronic device 10. The handheld device 10C may represent, for example, a tablet computer, or one of various portable computing devices. By way of example, the handheld device 10C may be a tablet-sized embodiment of the electronic device 10, which may be, for example, a model of an iPad® available from Apple Inc. of Cupertino, California.

Turning to FIG. 5, a computer 10D may represent another embodiment of the electronic device 10 of FIG. 1. The computer 10D may be any computer, such as a desktop computer, a server, or a notebook computer, but may also be a standalone media player or video gaming machine. By way of example, the computer 10D may be an iMac®, a MacBook®, or other similar device by Apple Inc. It should be noted that the computer 10D may also represent a personal computer (PC) by another manufacturer. A similar enclosure 36 may be provided to protect and enclose internal components of the computer 10D such as the display 18. In certain embodiments, a user of the computer 10D may interact with the computer 10D using various peripheral input devices, such as the keyboard 22A or mouse 22B (e.g., input structures 22), which may connect to the computer 10D.

Similarly, FIG. 6 depicts a wearable electronic device 10E representing another embodiment of the electronic device 10 of FIG. 1 that may be configured to operate using the techniques described herein. By way of example, the wearable electronic device 10E, which may include a wristband 43, may be an Apple Watch® by Apple, Inc. However, in other embodiments, the wearable electronic device 10E may include any wearable electronic device such as, for example, a wearable exercise monitoring device (e.g., pedometer, accelerometer, heart rate monitor), or other device by another manufacturer. The display 18 of the wearable electronic device 10E may include a touch screen display 18 (e.g., LCD, OLED display, active-matrix organic light emitting diode (AMOLED) display, and so forth), as well as input structures 22, which may allow users to interact with a user interface of the wearable electronic device 10E.

The electronic device 10 may have one or more components to be operated with varying levels of voltage. As such, the electronic device 10 may include a switching regulator located on a die to facilitate conversion of an input direct-current (DC) voltage to a desired output DC voltage. As discussed above, implementing a switching regulator with one or more power stages disposed externally of a main package of the switching regulator may allow for heat generated within the main package to be dissipated externally of the main package.

Any of the devices 10 illustrated in FIGS. 1-6 may employ an integrated circuit assembly, such as the processor(s) 12 in FIG. 1, that produce heat that can be dissipated using a thermal management module in accordance with the present disclosure. For example, the thermal management module is configured to transfer heat away from the integrated circuit assembly, such as the processor(s) 12 in FIG. 1, to a condenser section of the thermal management module, the enclosure 36 of the electronic device 10, an ambient environment, or any combination thereof. The thermal management module, described in detail below, may include a variety of features configured to enable a relatively thin form factor of the thermal management module, a relatively high heat transfer efficiency, a relatively low cost, or any combination thereof.

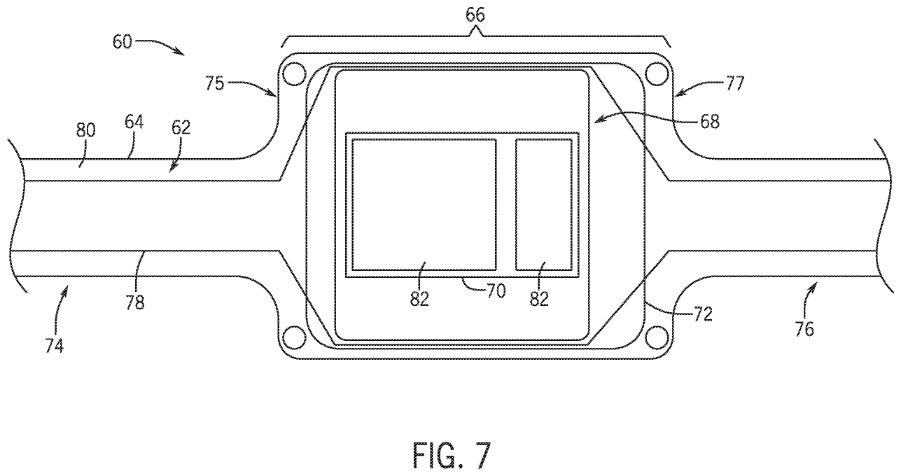

With the foregoing in mind, FIG. 7 is a front view of an embodiment of a portion of a thermal management module 60 for the electronic device 10 of FIG. 1. In the illustrated embodiment, the thermal management module includes a passage 62 defined by a housing 64, the passage 62 having a variable cross-sectional size (e.g., cross-sectional area, width, or height). Further, the thermal management module 60 includes an evaporator section 66 configured to be disposed adjacent to an integrated circuit assembly 68. The integrated circuit assembly 68 includes circuitry 70 (e.g., processing circuitry) disposed on, disposed in, or otherwise integrated with a die, such as a silicon or other semiconductor die, disposed on a substrate 72. The substrate 72 may be, for example, a printed circuit board (PCB), multilayer printed circuit board (MLB), flame retardant-4 (FR-4) material, etc.

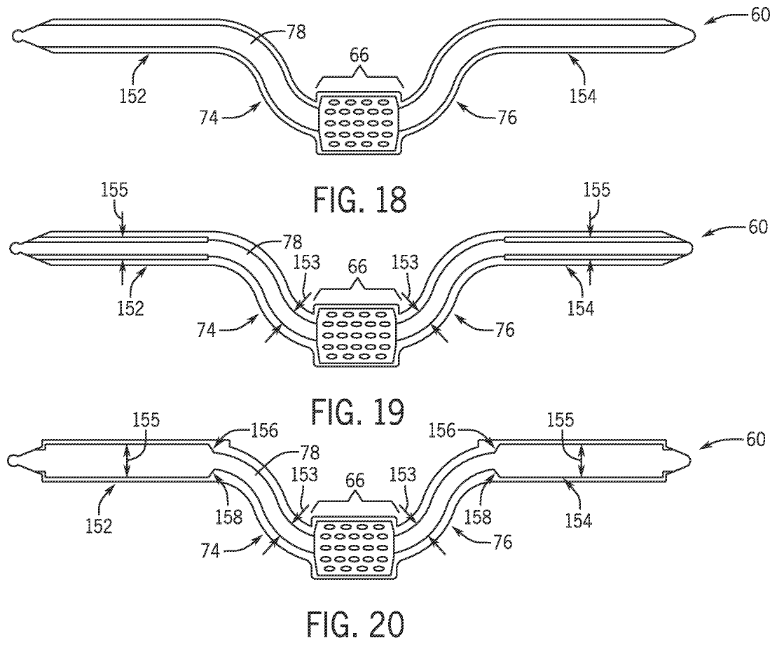

The passage 62 defined by the housing 64 of the thermal management module 60 is configured to retain a fluid conveyed between the evaporator section 66 and one or more condenser sections of the thermal management module 60 via one or more adiabatic sections of the thermal management module 60. In the illustrated embodiment, a first adiabatic section 74 extends from a first side 75 of the evaporator section 66 and a second adiabatic section 76 extends from a second side 77 of the evaporator section 66 opposing the first side 75. The condenser sections are not shown in the illustrated embodiment, but it should be understood that a first condenser section extends from the first adiabatic section 74 and a second condenser section extends from the second adiabatic section 76. For example, as described in detail below, a liquid form of the fluid is conveyed from the condenser sections, through the adiabatic sections 74, 76, and to the evaporator section 66, and a vapor form of the fluid is conveyed from the evaporator section 66, through the adiabatic sections 74, 76, and to the condenser sections. The condenser sections will be described in greater detail with reference to later drawings (e.g., FIGS. 18-20). It should be noted that, in some embodiments, the adiabatic sections 74, 76 may not be entirely adiabatic, and that “adiabatic sections” may be used as a naming convention in such embodiments (e.g., to denote the portion of the module extending between the evaporator section 66 and the condenser sections described in detail with reference to later drawings).

A sintered powder layer 78, referred to in certain instances of the present disclosure as a wick or a sintered wick, extends through various portions of the passage 62, including through the evaporator section 66, the adiabatic sections 74, 76, and the condenser sections extending from the adiabatic sections 74, 76. While various embodiments of the present disclosure include the sintered powder layer 78, described in detail below, it should be understood that the wick may additionally or alternatively include a paste (e.g., a porous paste), a gel (e.g., a porous gel), or a wire (e.g., a porous wire). The sintered powder layer 78 in FIG. 7 may be formed by heating a powder, such as a copper powder, to just below a melting point of the copper powder, causing a coalescence of the powder particles with pores between various formations of the coalesced powder particles. In general, the sintered powder layer 78 is configured to convey the liquid form of the fluid (e.g., via the pores) from the condenser sections, through the adiabatic sections 74, 76, and to the evaporator section 66.

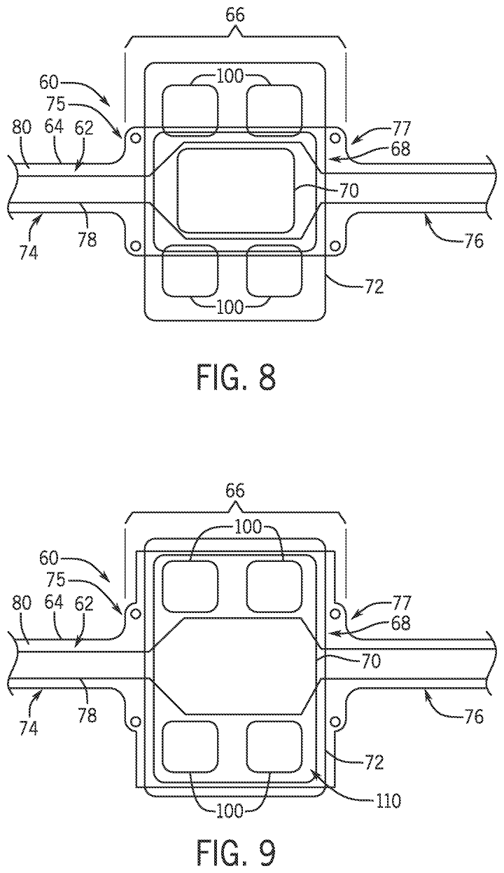

Heat generated by the integrated circuit assembly 68 (e.g., by the circuitry 70) is transferred to the liquid form of the fluid in the evaporator section 66, causing the liquid form of the fluid to evaporate to the vapor form of the fluid. A void 80 in the passage 62, which may be defined between the sintered powder layer 78 and the housing 64, is configured to convey the vapor form of the fluid from the evaporator section 66, through the adiabatic sections 74, 76, and to the condenser sections extending from the adiabatic sections 74, 76. In some embodiments, one or more columns 82 (referred to in certain instances of the present disclosure as pillars) extend from the sintered powder layer 78 and toward the integrated circuit assembly 68. That is, the one or more columns 82 are disposed underneath the integrated circuit assembly 68 and above the sintered powder layer 78 from the illustrated perspective. In the illustrated embodiment, the one or more columns 82 are spatially aligned with (e.g., overlapping) the circuitry 70 of the integrated circuit assembly 68. In this way, the one or more columns are configured to transfer heat generated by the circuitry 70 toward the sintered powder layer 78, which transfers the heat to the fluid (e.g., liquid form of the fluid) as described above. In the illustrated embodiment, the sintered powder layer 78 includes a generally octagonal shape in the evaporator section 66 and a generally rectangular shape in each of the adiabatic sections 74, 76 (and/or corresponding condenser sections), although other shapes are also possible in accordance with the present disclosure. Further, various alignment features of the thermal management module 60 relative to the integrated circuit assembly 68 are possible, as described in detail below with reference to FIGS. 8-10.

FIGS. 8-10 are front views of embodiments of a portion of the thermal management module 60 for the electronic device 10 of FIG. 1. As previously described, the thermal management module 60 is configured to transfer heat away from the integrated circuit assembly 68 spatially aligned with (e.g., overlapping) the evaporator section 66 of the thermal management module 60. In each of FIGS. 8-10, dynamic random-access memory (DRAM) circuitry 100 (or other memory storage device) is disposed in, disposed on, or otherwise integrated with the substrate 72 of the integrated circuit assembly 68. In FIG. 8, the sintered powder layer 78 is spatially aligned with (e.g., overlaps) the circuitry 70 of the integrated circuit assembly 68, but does not overlap with the DRAM circuitry 100. Likewise, in FIG. 9, the sintered powder layer 78 is spatially aligned with (e.g., overlaps) the circuitry 70 of the integrated circuit assembly 68, but does not overlap with the DRAM circuitry 100. However, in FIG. 9, a passive spreader 110 including a copper or aluminum material that is spatially aligned with (e.g., overlaps) the DRAM circuitry 100. In certain embodiments, the passive spreader 110 contacts the sintered powder layer 78 and is configured to transfer heat generated by the DRAM circuitry 100 to the sintered powder layer 78 and, thus, the liquid form of the fluid at the evaporator section 66. In FIG. 9, the housing 64 of the thermal management module 60 is larger at the evaporator section 66 than in FIG. 8, such that the housing 64 is sized to receive the passive spreader 110. For example, the housing 64 in FIG. 9 is large enough to house the passive spreader 110 while the passive spreader 110 is spatially aligned with (e.g., overlapping) the DRAM circuitry 100.

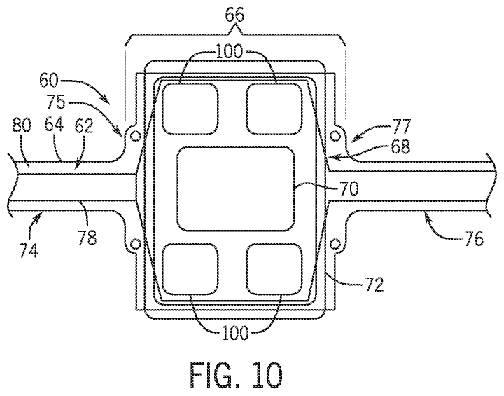

In FIG. 10, the sintered powder layer 78 is spatially aligned with (e.g., overlaps) the circuitry 70 and the DRAM circuitry 100. Similar to FIG. 9, the housing 64 in FIG. 10 is large enough to house the sintered powder layer 78 while the sintered powder layer 78 is spatially aligned with (e.g., overlapping) the DRAM circuitry 100. Although the one or more columns 82 in FIG. 7 are not illustrated in FIGS. 8-10, it should be understood that the one or more columns 82 in FIG. 7 may be employed in any of the embodiments illustrated in FIGS. 8-10. For example, the one or more columns 82 in FIG. 7 may be employed to extend within the evaporator section 66 illustrated in FIGS. 8-10 and between the sintered powder layer 78 and the circuitry 70. In certain embodiments, the one or more columns 82 in FIG. 7 may also be employed to extend between the sintered powder layer 78 and the DRAM circuitry 100 in FIGS. 8-10. It should be noted that, in some embodiments, the evaporator section 66 may be spatially aligned with other features of the integrated circuit assembly 68, such as one or more voltage regulators, one or more power management units (PMUs), one or more field-effect transistors (FETs), one or more inductors, one or more coupled inductor voltage regulators (CLVRs), etc. It should be noted that, in each of FIGS. 8-10, each DRAM 100 may be integrated with or otherwise include a corresponding dedicated die, and each instance of the processing circuitry 70 may be integrated with or otherwise include a corresponding dedicated die (e.g., separate from the die of each DRAM 100). In other embodiments, a common die may be employed for multiple components, such as a common die for the DRAM 100 and the processing circuitry 70.

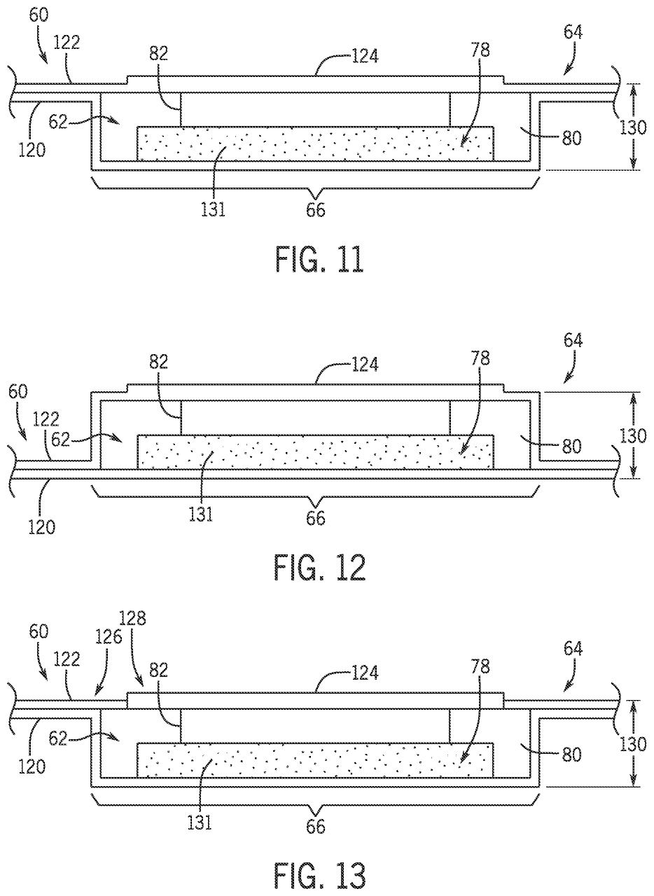

FIGS. 11-15 are cross-sectional side views of embodiments of a portion of the thermal management module 60 for the electronic device 10 of FIG. 1, where the cross-sections are taken through the evaporator section 66 of the thermal management module 60. In each of FIGS. 11-15, the passage 62 formed by the housing 64 of the thermal management module 60 includes, disposed therein, the sintered powder layer 78, the void 80 between the sintered powder layer 78 and the housing 64, and the one or more columns 82 (e.g., pillars) extending from the sintered powder layer 78 to the housing 64. Further, in each of FIGS. 11-15, the housing 64 includes at least a first housing portion 120 (e.g., lower housing portion) and a second housing portion 122 (e.g., upper housing portion) coupled to the first housing portion 120 to seal the passage 62. Various sealing mechanisms will be described in detail with reference to later drawings.

In FIG. 11, the first housing portion 120 includes steel (e.g., stainless steel or another steel alloy) and the second housing portion 122 includes copper. Further, the passage 62 is recessed downwardly from an integrated circuit assembly platform 124 defined on the second housing portion 122 and configured to receive or otherwise be disposed adjacent to the integrated circuit assembly 68 (or componentry thereof) illustrated in FIGS. 7-10. In FIG. 12, the first housing portion 120 includes steel (e.g., stainless steel or another steel alloy) and the second housing portion 122 includes copper. Further, the passage 62 is elevated upwardly to the integrated circuit assembly platform 124 defined on the second housing portion 122. In FIG. 13, the first housing portion 120 includes steel (e.g., stainless steel or another steel alloy) and the second housing portion 122 includes a first part 126 with steel (e.g., stainless steel or another steel alloy) and a second part 128 with copper, where the second part 128 defines the integrated circuit assembly platform 124. In some embodiments, the second part 128 is embedded in a skin forming the first part 126. In general, the integrated circuit assembly platform 124 may be configured to receive the integrated circuit assembly. In other words, the integrated circuit assembly platform 124 may be a portion of the housing that interfaces with the heat source(s).

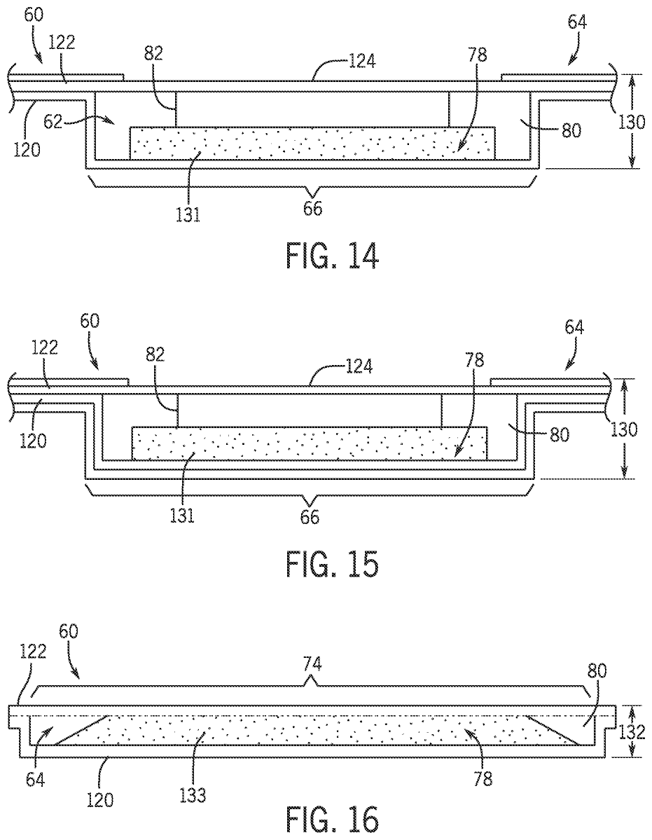

In FIG. 14, the first housing portion 120 includes steel (e.g., stainless steel or another steel alloy) and the second housing portion 122 includes a steel-copper clad material (e.g., stainless steel-copper clad material or another steel alloy-copper clad material), where the steel (e.g., stainless steel or another steel alloy) is removed at the integrated circuit assembly platform 124. In FIG. 15, both the first housing portion 120 and the second housing portion 122 include a steel-copper clad material (e.g., stainless steel-copper clad material or another steel alloy-copper clad material), where the steel (e.g., stainless steel or another steel alloy) is removed from the second housing portion 122 at the integrated circuit assembly platform 124.

In general, steel (e.g., stainless steel or another steel alloy) is employed to provide structural integrity of the thermal management module 60, and copper is employed to provide thermal benefits (e.g., improved heat transfer efficiency) of the thermal management module 60. For example, employing copper at the integrated circuit assembly platform 124, as shown in each of FIGS. 11-15, may improve heat transfer from the integrated circuit assembly 68 illustrated in FIGS. 7-10 to the sintered powder layer 78 and corresponding fluid (e.g., via the one or more columns 82). In any of FIGS. 11-15, or in another embodiment, the first housing portion 120, the second housing portion 122, another component of the housing, or any combination thereof may additionally or alternatively include carbon fiber composite, aluminum, one or more fitted metal interfaces, or any combination thereof.

In each of FIGS. 11-15, the thermal management module 60 includes a height 130 (or thickness) at the evaporator section 66 from an upper most surface of the thermal management module 60 to a lower most surface of the thermal management module 60. In general, the height 130 of the thermal management module 60 at the evaporator section 66 may be less than a height of the thermal management module 60 at the adiabatic section(s) and/or the condenser section(s) of the thermal management module 60. Further, in each of FIGS. 11-15, the sintered powder layer 78 (e.g., at the evaporator section 66) includes pores 131 having a first size or density that is different than (e.g., less than) those of the adiabatic section(s) and/or the condenser section(s) of the thermal management module 60.

For example, FIG. 16 is a cross-sectional side view of an embodiment of a portion of the thermal management module 60 for the electronic device 10 of FIG. 1, where the cross-section is taken through one of the adiabatic sections or one of the condenser sections of the thermal management module 60, such as the adiabatic section 74 illustrated in FIGS. 7-10. As previously described, the first housing portion 120 and the second housing portion 122 are coupled to form the passage 62 in which the sintered powder layer 78 and the void 80 are disposed.

As shown, the adiabatic section 74 includes a height 132 (or thickness). The height 132 of the adiabatic section 74 is less than the height 130 of the various embodiments of the evaporator section 66 illustrated in FIGS. 11-15. Depending on the embodiment, the height 132 of the adiabatic section 74 in FIG. 16 is less than 75%, less than 66%, less than 50%, less than 33%, or less than 25% of the height 130 of the evaporator section 66 in FIGS. 11-15. Based at least on the differences in the heights 130, 132 described above, a first cross-sectional area of the adiabatic section 74 in FIG. 16 is less than a second cross-sectional area of the various embodiments of the evaporator section 66 illustrated in FIGS. 11-15, where the cross-sections in FIGS. 11-16 are taken substantially parallel to each other and orthogonal to an average flow direction of the fluid through the thermal management module 60. In other words, the passage 62 at the adiabatic section 74 in FIG. 16 is smaller than the passage 62 at the evaporator section 66 illustrated in FIGS. 11-15. Based at least on these relative sizing features, the evaporator section 66 is sized to receive the sintered powder layer 78 and the one or more columns 82 (e.g., pillars), improving heat transfer efficiency of the thermal management module 60, and the adiabatic section 74 is sized to exclude the one or more columns 82 (e.g., pillars), thereby reducing a form factor of at least a portion of the thermal management module 60. While the above-described features in FIG. 16 are described with respect to the adiabatic section 74, it should be understood that the same or similar features may be employed at the condenser section extending from the adiabatic section 74. The condenser section will be described in detail with reference to later drawings.

Further, the sintered powder layer 78 at the adiabatic section 76 (and/or condenser section) includes pores 133 having a second size or density that is different than (e.g., greater than) the pores 131 of the evaporator section 66 illustrated in FIGS. 11-15. Specific pore sizes and/or densities may be generated by heating the powder of the sintered powder layer 78 to varying degrees or for varying lengths of time. While the pores 133 in FIG. 16 are described above as being larger than and/or denser than the pores 131 in FIGS. 11-15, in other embodiments, the pores 133 may be smaller than and/or less dense than the pores 131 in FIGS. 11-15. Further, pore size and/or density may be gradually varied over an entirety of the sintered powder layer 78 in certain embodiments (e.g., as opposed to sharp distinctions in pore size and/or density between various section of the sintered powder layer 78). In other words, a gradient of pore size or density through the sintered powder layer 78 may exist in certain embodiments. Further, in certain embodiments, pore size or density at a particular segment of the sintered powder layer 78 may be a function of length, cross-sectional area, or some other dimension of the sintered powder layer 78 at said segment.

It should be noted that the adiabatic section 74 in FIG. 18 and/or the condenser section(s) described in detail below may be disposed at different elevations than the embodiments of the evaporator section 66 in FIGS. 11-15. For example, the height 132 of the adiabatic section 74 in FIG. 16 (and the heights of the condenser sections descried in detail below) may be offset from the height 130 of the embodiments of the evaporator section 66 in FIGS. 11-15, while still maintaining a fluid coupling between such sections of the module. In this way, the evaporator section may extend above and/or below the adiabatic sections, the condenser sections, or both.

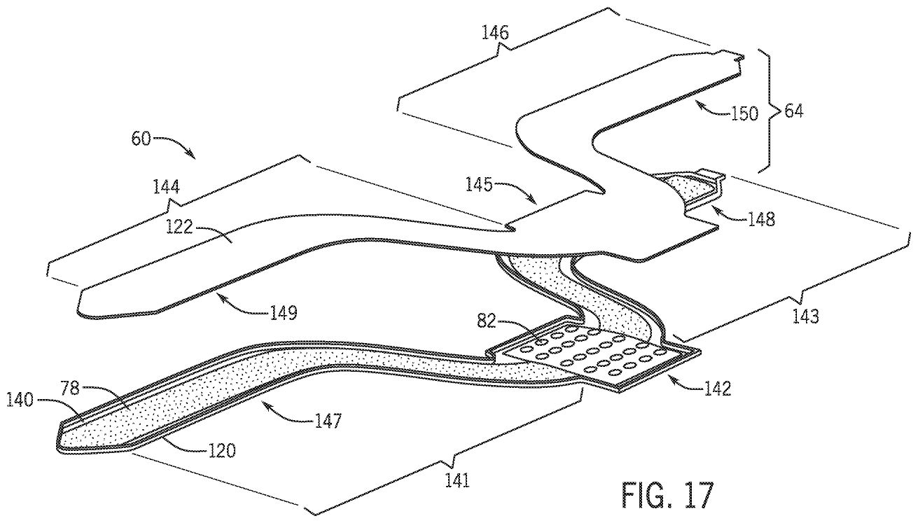

FIG. 17 is a perspective view of an embodiment of the thermal management module 60 for the electronic device 10 of FIG. 1. In the illustrated embodiment, the housing 64 includes the first housing portion 120 and the second housing portion 122 configured to be coupled to the first housing portion 120. The first housing portion 120 and the second housing portion 122 are configured to be coupled via various sealing features described in detail with reference to later drawings. The sintered powder layer 78 in FIG. 17 is disposed on an inner surface 140 of the first housing portion 120 and extends through a first arm 141 (or wing) of the first housing portion 120, a central portion 142 (e.g., rectangular portion) of the first housing portion 120, and a second arm 143 (or wing) of the first housing portion 120. The second housing portion 122 includes a first arm 144 (or wing) configured to be coupled to the first arm 141 of the first housing portion 120 (e.g., to form the first adiabatic section 74 illustrated in at least FIGS. 7-10 and the condenser section illustrated in FIGS. 18-20 and described in detail below), a central portion 145 (e.g., rectangular portion) configured to be coupled to the central portion 142 of the first housing portion 120 (e.g., to form the evaporator section 66 illustrated in at least FIGS. 7-10), and a second arm 146 (or wing) configured to be coupled to the second arm 143 of the first housing portion 120 (e.g., to form the second adiabatic section 76 illustrated in FIGS. 7-10 and the condenser section illustrated in FIGS. 18-20 and described in detail below).

As shown, the arms 141, 143 of the first housing portion 120 and the arms 144, 146 of the second housing portion 122 may include curvilinear shapes (e.g., bends or S-shapes) to offset distal end segments 147, 148 of the first housing portion 120 from the central portion 142 and distal end segments 149, 150 of the second housing portion 122 from the central portion 145. The distal end segment 147 of the first arm 141 of the first housing portion 120 and the distal end segment 149 of the first arm 144 of the second housing portion 122 may be coupled to form a first condenser section of the thermal management module 60, describe in greater detail with reference to FIGS. 18-20. Further, the distal end segment 148 of the second arm 143 of the first housing portion 120 and the distal end segment 150 of the second arm 146 of the second housing portion 122 may be coupled to form the second condenser section of the thermal management module 60, described in greater detail with reference to FIGS. 18-20.

Although not shown in the illustrated embodiment, the distal end segment 147 of the first arm 141 of the first housing portion 120 and the distal end segment 149 of the first arm 144 of the second housing portion 122, when joined to form the first condenser section, may include, receive, or otherwise be disposed adjacent to heat fins configured to extract heat from the thermal management module 60 (e.g., causing the vapor form of the fluid therein to condense into the liquid form of the fluid, which is conveyed through pores in the sintered powder layer 78 toward the central portions 142, 145). Likewise, the distal end segment 148 of the second arm 143 of the first housing portion 120 and the distal end segment 150 of the second arm 146 of the second housing portion 122, when joined to form the second condenser section, may include, receive, or otherwise be disposed adjacent to heat fins configured to extract heat from the thermal management module 60 (e.g., causing the vapor form of the fluid therein to condense into the liquid form of the fluid, which is conveyed through pores in the sintered powder layer 78 toward the central portions 142, 145). Additionally or alternatively, one or more airflows generated by one or more air movers (e.g., fans) may be biased over the condenser sections. In some embodiments, the heat fin(s), fan(s), and/or other heat sink features may be considered a part of the condenser sections. The condenser sections of the thermal management module 60 are described in detail below with reference to FIGS. 18-20.

FIGS. 18-20 are top views of embodiments of the thermal management module 60 for the electronic device 10 of FIG. 1, illustrating different geometries of the sintered powder layer 78 (e.g., sintered wick), among other features. The thermal management modules 60 in FIGS. 18-20 each include the evaporator section 66, the first and second adiabatic sections 74, 76, and first and second condenser sections 152, 154 extending from the first and second adiabatic sections 74, 76, respectively. As previously described, the condenser sections 152, 154 may be disposed adjacent heat fins, one or more air movers (e.g., fans), or both, where the heat fins, one or more air flows from the one or more fans, or both are configured to extract heat from the condenser sections 152, 154, thereby causing the vapor form of the fluid in the condenser sections 152, 154 to condense into the liquid form of the fluid conveyed back toward the evaporator section 66.

The thermal management module 60 in FIG. 18 includes a substantially constant cross-sectional size and shape of the sintered powder layer 78. In FIG. 19, a width 153 of the sintered powder layer 78 at the adiabatic sections 74, 76 is smaller than a width 155 of the sintered powder layer 78 at the condenser sections 152, 154. Likewise, in FIG. 20, the width 153 of the sintered powder layer 78 at the adiabatic sections 74, 76 is smaller than the width 155 of the sintered powder layer 78 at the condenser sections 152, 154. In general, the relatively slender width 153 of the sintered powder layer 78 in the adiabatic sections 74, 76 of the thermal management modules 60, as illustrated in FIGS. 19 and 20, may allow for enhanced transport of the vapor form of the liquid from the evaporator section 66 to the condenser sections 152, 154. However, the sintered powder layer 78 at the condenser sections 152, 154 in FIG. 19 may include a tapered cross-sectional height (e.g., similar to the cross-sectional profile of the sintered powder layer 78 illustrated in FIG. 16), whereas the sintered powder layer 78 at the condenser sections 152, 154 in FIG. 20 may include a substantially constant cross-sectional height. Additionally or alternatively, the sintered powder layer 78 may include angled flare portions 156, 158 as the sintered powder layer 78 transitions from the adiabatic sections 74, 76 to the condenser sections 152, 154, respectively.

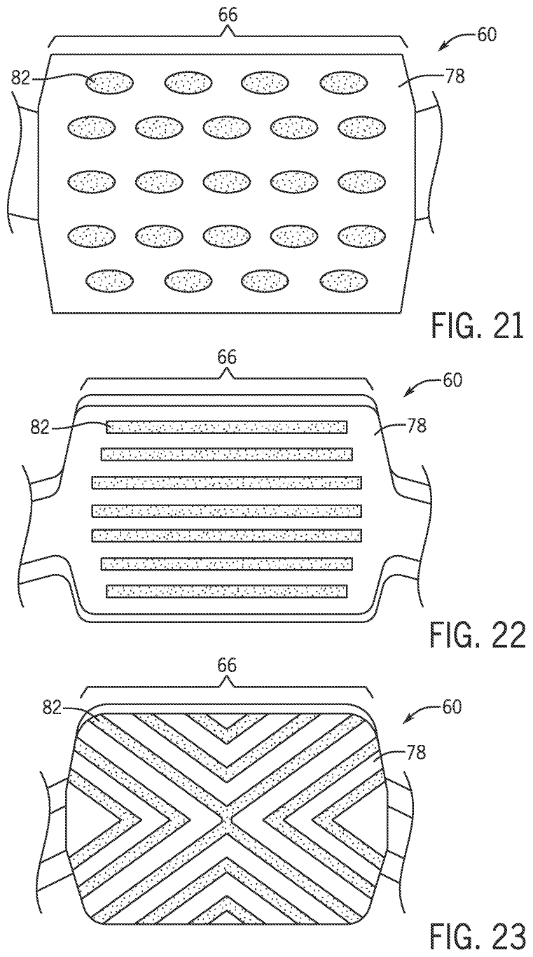

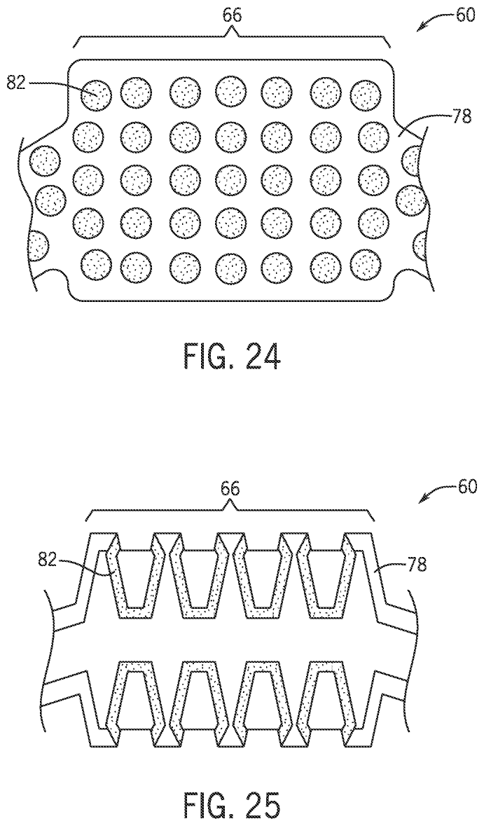

FIGS. 21-25 are front cross-sectional views of various embodiment of a portion of the evaporator section 66 of the thermal management module 60 for the electronic device 10 of FIG. 1, including the one or more columns 82 (e.g., pillars) configured to extend from the sintered powder layer 78 to, for example, the integrated circuit assembly platform 124 illustrated in FIGS. 11-15. For example, in FIG. 21, each of the columns 82 includes a curvilinear, non-circular (e.g., oval or elliptical) cross-section. In FIG. 22, each of the columns 82 includes a rectangular or strip-shaped cross-section. In FIG. 23, cross-sections of the columns 82 form a herringbone-like pattern. For example, one of the columns 82 includes an X-shaped cross-section and the other of the columns 82 include arrow-shaped cross-sections pointing toward a center of the X-shape. In FIG. 24, each of the columns 82 includes a circular cross-section. In FIG. 25, each of the columns 82 includes a cross-section resembling the top of a trapezoid. Cross-sectional shapes of the columns 82 may vary depending on application (e.g., depending on the type of electronic device and/or integrated circuit assembly being cooled by the thermal management module 60). Further, FIGS. 21-25 are provided as non-limiting examples. Other shapes of the columns 82 are also possible in accordance with the present disclosure.

While the above-described columns 82 in FIGS. 21-25 are shown and described with respect to the evaporator section 66 of the thermal management module 60, in certain embodiments, the same or similar columns 82 may be disposed in the condenser sections of the thermal management module 60 (e.g., the condenser sections 152, 154 in FIGS. 18-20) and/or the adiabatic section(s) of the thermal management module 60 (e.g., the adiabatic sections 74, 76 in FIGS. 18-20). Such columns 82 in the condenser section(s) and/or the adiabatic section(s) of the thermal management module 60 may be employed along with, or in lieu of, the sintered powder layer 78 described in detail above.

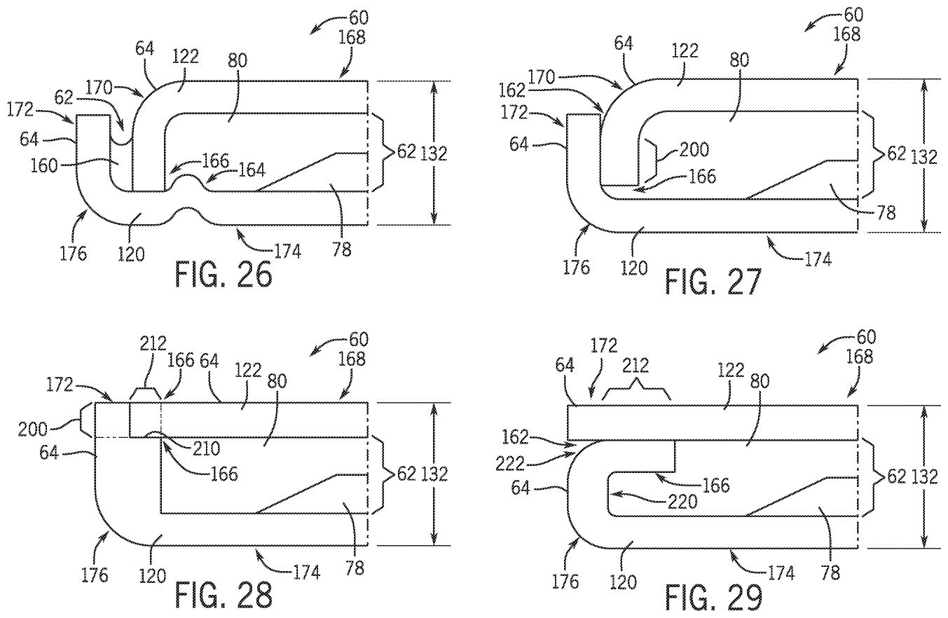

As previously described and illustrated, for example, in FIGS. 11-17 of the present disclosure, the thermal management module 60 may include first and second housing portions 120, 122 coupled to seal the passage 62 configured to receive the fluid employed to cool an integrated circuit assembly. FIGS. 26-29 are cross-sectional side views of various coupling and/or sealing (e.g., hermetic sealing) mechanisms configured to couple the first housing portion 120 and the second housing portion 122 of the housing 64 of the thermal management module 60.

For example, FIG. 26 is a cross-sectional side view of an embodiment of a sealing mechanism for sealing the first and second housing portions 120, 122 of the housing 64 of the thermal management module 60 for the electronic device 10 of FIG. 1 via a brazing material 160 disposed in a seam 162 between the first and second housing portions 120, 122. In the illustrated embodiment, a ridge 164 is formed in the first housing portion 120. An end 166 (e.g., distal end) of the second housing portion 122, which may extend at an approximately 90-degree angle relative to a body 168 of the second housing portion 122 by way of a bent segment 170 of the second housing portion 122, is positioned outward from the ridge 164 of the first housing portion 120. The ridge 164 may be employed to locate the end 166 of the second housing portion 122 between the ridge 164 and an end 172 (e.g., distal end) of the first housing portion 120, while leaving a sufficient space (e.g., the seam 162) between the end 166 of the second housing portion 122 and the end 172 of the first housing portion 120 for receiving the brazing material 160. The end 172 of the first housing portion 120 may extend at an approximately 90-degree angle relative to a body 174 of the second housing portion 122 by way of a bent segment 176 of the second housing portion 122.

The brazing material 160 may be, for example, silver, copper (e.g., copper alloy), or some other fusible solder material that, upon heating, forms a bead extending along the seam 162 between the first housing portion 120 and the second housing portion 122. It should be noted that the brazing material 160 may extend along an entirety of a perimeter of the thermal management module 60 such that the passage 62 is sealed (e.g., hermetically sealed) via the first housing portion 120, the second housing portion 122, and the brazing material 160.

FIG. 27 is a cross-sectional side view of an embodiment of a sealing mechanism for sealing the first and second housing portions 120, 122 of the housing 64 of the thermal management module 60 for the electronic device 10 of FIG. 1. For example, in FIG. 27, the passage 62 of the thermal management module 60 is sealed via a lap welded interface 200 between the end 172 of the first housing portion 120 and the end 172 of the second housing portion 122. Although not shown in the illustrated embodiment, brazing material may be disposed in the seam 162 formed between the first and second housing portions 120, 122 (e.g., in addition to the lap welded interface 200). As shown, the lap welded interface 200 in FIG. 27 is oriented in a direction perpendicular to the height 132 of the thermal management module 60. The lap welded interface 200 may be established, for example, via a laser welding technique.

FIG. 28 is a cross-sectional side view of an embodiment of a sealing mechanism for sealing the first and second housing portions 120, 122 of the housing 64 of the thermal management module 60 for the electronic device 10 of FIG. 1. For example, in FIG. 28, a ledge 210 may be formed at the end 172 of the first housing portion 120, where the end 166 of the second housing portion 122 is configured to be disposed on the ledge 210. In this way, the end 166 of the second housing portion 122 and the end 172 of the first housing portion 120 contact each other across two surfaces. Thus, the first housing portion 120 and the second housing portion 122 may be joined via two lap welded interfaces 200, 212 extending in opposing (e.g., transverse, perpendicular) directions. That is, the lap welded interface 200 may extend in a direction perpendicular to the height 132 of the thermal management module 60, and the lap welded interface 212 may extend in a direction parallel to the height 132 of the thermal management module 60.

FIG. 29 is a cross-sectional side view of an embodiment of a sealing mechanism for sealing the first and second housing portions 120, 122 of the housing 64 of the thermal management module 60 for the electronic device 10 of FIG. 1. In the illustrated embodiment, the first housing portion 120 includes the body 174, the bent segment 176, a segment 220 extending from the bent segment 176, an additional bent segment 222, and the end 166 extending from the additional bent segment 222. In this way, the end 166 of the first housing portion 120 extends substantially parallel to the body 174 of the first housing portion 120. Further, the end 166 of the first housing portion 120 is coupled to the body 168 of the second housing portion 122 via the lap welded interface 212 extending in a direction that is parallel to the height 132 of the thermal management module 60. The lap welded interface 212 facilitates a sealing of the passage 62 defined by the first housing portion 120 and the second housing portion 122. In some embodiments, the seam 162 between the first housing portion 120 and the second housing portion 122 receives a brazing material (e.g., the brazing material 160 illustrated in FIG. 26) to further reinforce the sealing of the passage 62.

In general, the features illustrated in FIGS. 26-29 facilitate a sealing of the passage 62 of the thermal management module 60 such that the fluid within the passage 62 does not leak to an external environment. Further, the sealing mechanisms are configured to seal the passage 62 without substantially increasing a footprint of the thermal management module 60. While cross-sectional views of FIGS. 26-29 illustrate sealing features at a condenser section of the thermal management module 60, it should be understood that such sealing features may extend about an entirety of the thermal management module 60, including any condenser section(s) and the evaporator section. In other words, the brazing material 160 and/or the lap welded interfaces 200, 212 may extend about an entirety of a perimeter of the first housing portion 120 and the second housing portion 122 to seal (e.g., hermetically seal) an entirety of the passage 62.

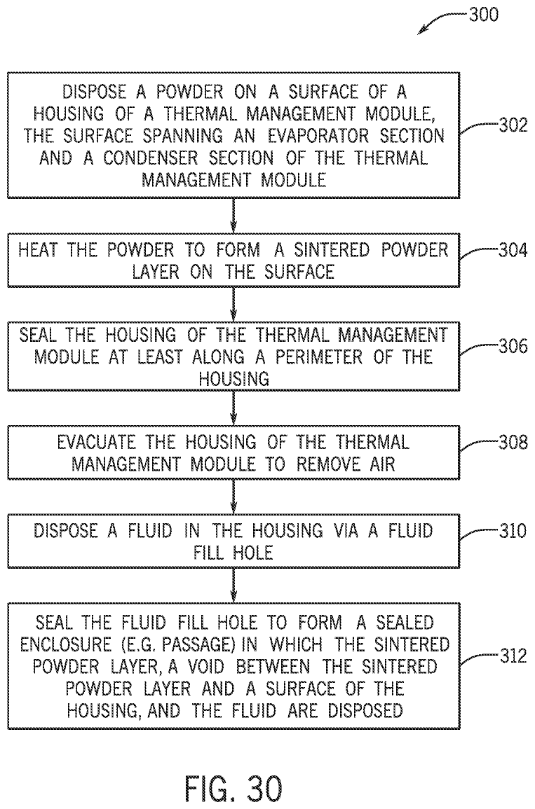

FIG. 30 is a process flow diagram illustrating a method 300 of manufacturing a thermal management module for the electronic device of FIG. 1. In the illustrated embodiment, the method 300 includes disposing (block 302) a powder on a surface of a housing of the thermal management module, the surface spanning an evaporator section and a condenser section of the thermal management module. In some embodiments, the powder includes a copper powder.

The method 300 also includes heating (block 304) the powder to form wick (e.g., a sintered powder layer or sintered wick). For example, heating the powder may cause powder particles to coalesce to form the sintered powder layer. The sintered powder layer may be a continuum from the evaporator section to the condenser section(s) (e.g., as opposed to discrete segments). Further, pores may be formed between various formations of the coalesced powder of the sintered powder layer. In some embodiments, the powder is heated to varying degrees in various sections of the thermal management module, such that pore size or density is variable between the various sections of the thermal management module. As an example, the pore size or density of the pores in the sintered powder layer may be greater in the condenser section than in the evaporator section.

The method 300 also includes sealing (block 306) the housing at least along a perimeter of the housing. For example, the housing may include a first housing portion (e.g., on which the above-described wick is disposed) and a second housing portion configured to be coupled with the first housing portion. Various brazing and/or welding techniques may be employed to couple the first housing portion with the second housing portion, as described above with respect to FIGS. 26-29. For example, perimeters of the first housing portion and the second housing portion may be overlapped and lap welded together to seal the housing and form the sealed passage. Additionally or alternatively, a brazing material may be disposed in a seam formed by or between the perimeters of the first housing portion and the second housing portion. In some embodiments, employing the first housing portion and the second housing portion enables variable cross-sectional area of the sealed passage. For example, a first cross-sectional area of the sealed passage at the condenser section and/or the adiabatic section may be smaller than a second cross-sectional area of the sealed passage at the evaporator section. In this way, a form factor of at least the condenser section and/or the adiabatic section may be smaller than traditional configurations. Additionally or alternatively, the above-described sizing features may improve heat transfer efficiency over traditional configurations

The method 300 also includes evacuating (block 308) the housing of the thermal management module to remove air (e.g., partial or substantially full evacuation), and disposing (block 310) a fluid in the housing (e.g., after evacuating the housing) via a fluid fill hole and/or nipple. As previously described, the fluid may be employed to change phases in order to extract heat from processing circuitry of an integrated circuit assembly of the electronic device. Indeed, in the evaporator section, a liquid form of the fluid may be heated to generate a vapor form of the fluid conveyed to the condenser section (e.g., via an adiabatic section between the condenser section and the evaporator section). Further, in the condenser section, the vapor form of the fluid may be cooled and/or condensed to form the liquid form of the fluid conveyed to the evaporator section (e.g., via the adiabatic section between the condenser section and the evaporator section). In some embodiments of the method 300, one or more columns are coupled, at the evaporator section of the thermal management module, to the sintered powder layer and the housing of the thermal management module. In this way, the housing, the one or more columns, and the sintered powder layer define a conductive path for transferring heat from processing circuitry of the integrated circuit assembly toward the fluid.

The method 300 also includes sealing (block 312) the fluid fill hole to form a sealed enclosure (e.g., passage) in which the sintered powder layer, a void between the sintered powder layer and the housing, and the fluid are disposed. In general, the void is configured to convey the vapor form of the fluid from the evaporator section to the condenser section (e.g., by way of the adiabatic section). The pores in the sintered powder layer are configured to convey the liquid form of the fluid from the condenser section to the evaporator section (e.g., by way of the adiabatic section).

It should be noted that an order of the steps of the method 300 described above should not be taken as implying that the steps could be not performed in other orders. Any suitable order of the steps (e.g., blocks 302, 304, 306, 308, 310, 312) may be employed in accordance with the present disclosure.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112 (f). However, for any claims containing elements designated in any other manner, it is intended that such elements are not to be interpreted under 35 U.S.C. 112 (f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. A thermal management module for an integrated circuit assembly, comprising:
a housing defining a sealed passage configured to receive a fluid and having a variable cross-sectional area;
a wick disposed within the sealed passage, wherein the wick forms pores configured to convey a liquid form of the fluid toward an evaporator section of the thermal management module; and
a void formed within the sealed passage between the wick and a wall of the housing, wherein the void is configured to convey a vapor form of the fluid toward a condenser section of the thermal management module.

2. The thermal management module of claim 1, wherein the pores formed by the wick comprise:
a first pore size or density adjacent to the evaporator section of the thermal management module; and
a second pore size or density adjacent to the condenser section of the thermal management module, wherein the second pore size or density is different than the first pore size or density.

3. The thermal management module of claim 1, wherein the housing comprises:
a first housing portion on which the wick is disposed; and
a second housing portion coupled with the first housing portion and comprising the wall.

4. The thermal management module of claim 3, comprising a brazing material disposed in a seam formed by the first housing portion and the second housing portion such that the brazing material, the first housing portion, and the second housing portion hermetically seal the sealed passage.

5. The thermal management module of claim 3, comprising a lap welded interface between a first perimeter of the first housing portion and a second perimeter of the second housing portion, wherein the lap welded interface, the first housing portion, and the second housing portion hermetically seal the sealed passage.

6. The thermal management module of claim 1, comprising a plurality of columns coupling the wick with the wall, wherein the plurality of columns is positioned in the evaporator section of the thermal management module.

7. (canceled)

8. The thermal management module of claim 1, wherein:
the wick comprises a sintered powder layer;
the sintered powder layer comprises copper; and
the housing comprises steel, copper, carbon fiber composite, aluminum, one or more fitted metal interfaces, or any combination thereof.

9. The thermal management module of claim 1, wherein:
the sealed passage comprises a first cross-section having a first cross-sectional area of the variable cross-sectional area at the evaporator section;
the sealed passage comprises a second cross-section having a second cross-sectional area of the variable cross-sectional area at the condenser section; and
the first cross-sectional area is greater than the second cross-sectional area, the first cross-section and the second cross-section being taken parallel to each other and orthogonal to an average flow direction of the fluid between the condenser section and the evaporator section.

10. A thermal management module for an integrated circuit assembly, comprising:
a sealed passage configured to house a fluid;
an evaporator section in the sealed passage, wherein the evaporator section is configured to extract heat from the integrated circuit assembly via the fluid to generate a vapor form of the fluid;
a condenser section in the sealed passage, wherein the condenser section is configured to extract heat from the fluid to generate a liquid form of the fluid;
a wick disposed within the sealed passage and forming pores configured to convey the liquid form of the fluid from the condenser section toward the evaporator section;
an integrated circuit assembly platform configured to receive the integrated circuit assembly; and
a void formed within the sealed passage adjacent to the wick, wherein the void is configured to convey the vapor form of the fluid from the evaporator section toward the condenser section, and wherein at least a portion of the void is between the integrated circuit assembly platform and the wick.

11. The thermal management module of claim 10, comprising a plurality of columns within the evaporator section and configured to extend from the wick toward the integrated circuit assembly.

12. (canceled)

13. The thermal management module of claim 10, comprising a housing, wherein the housing comprises:
a first housing portion on which the wick is disposed;
a second housing portion coupled with the first housing portion; and
a brazing material disposed in a seam formed by the first housing portion and the second housing portion such that the brazing material, the first housing portion, and the second housing portion hermetically seal the sealed passage.

14. The thermal management module of claim 10, comprising a housing, wherein the housing comprises:
a first housing portion on which the wick is disposed; and
a second housing portion coupled with the first housing portion, wherein the first housing portion overlaps with the second housing portion at a lap welded interface such that the first housing portion, the second housing portion, and the lap welded interface hermetically seal the sealed passage.

15. The thermal management module of claim 10, wherein:
the sealed passage comprises a variable cross-sectional area;
a first section of the wick comprises a first pore size or density of the pores;
a second section of the wick comprises a second pore size or density of the pores; and
the first pore size or density differs from the second pore size or density.

16. An integrated circuit assembly, comprising:
a substrate having processing circuitry thereon; and
a thermal management module comprising:
an evaporator section spatially aligned with the processing circuitry and configured to extract heat from the processing circuitry via a fluid to generate a vapor form of the fluid;
a condenser section positioned away from the processing circuitry and configured to extract heat from the fluid to generate a liquid form of the fluid;
a wick spanning the evaporator section and the condenser section, wherein the wick forms pores configured to convey the liquid form of the fluid from the condenser section toward the evaporator section; and
a void formed adjacent to the wick and spanning the evaporator section and the condenser section, wherein the void is configured to convey the vapor form of the fluid from the evaporator section toward the condenser section.

17. The integrated circuit assembly of claim 16, comprising one or more columns disposed in the evaporator section and extending from the wick to an integrated circuit platform assembly, wherein the integrated circuit platform assembly is defined by a housing of the thermal management module and configured to receive the substrate on which the processing circuitry is disposed, and the integrated circuit platform assembly, the one or more columns, and the wick are configured to establish a conductive path configured to transfer heat from the processing circuitry to the fluid.

18. The integrated circuit assembly of claim 16, wherein:
the evaporator section comprises a rectangular cross-sectional shape; and
a first portion of an adiabatic section of the thermal management module couples a first portion of the condenser section with a first side of the rectangular cross-sectional shape, and a second portion of the adiabatic section of the thermal management module couples a second portion of the condenser section with a second side of the rectangular cross-sectional shape.

19. The integrated circuit assembly of claim 16, comprising a housing defining a sealed passage in which the wick and the void are disposed, wherein the housing comprises:
a first housing portion on which the wick is disposed;
a second housing portion coupled with the first housing portion; and
a brazing material disposed in a seam formed by the first housing portion and the second housing portion such that the brazing material, the first housing portion, and the second housing portion hermetically seal the sealed passage.

20. The integrated circuit assembly of claim 16, comprising a housing defining a sealed passage in which the wick and the void are disposed, wherein the housing comprises:
a first housing portion;
a second housing portion; and
a lap weld between the first housing portion and the second housing portion such that the lap weld, the first housing portion, and the second housing portion hermetically seal the sealed passage.

21. The integrated circuit assembly of claim 16, wherein the wick comprises a sintered powder layer.

22. The integrated circuit assembly of claim 16, comprising one or more memory storage devices disposed on the substrate, wherein the evaporator section is spatially aligned with the one or more memory storage devices.

23-25. (canceled)
